(19) United States
(12) Patent Application Publication
(10) Pub. No.: US 2024/0414930 A1
(43) Pub. Date: Dec. 12, 2024

(54) ORGANIC PHOTODIODE FOR DETECTING SWIR, METHOD FOR MANUFACTURING THE SAME, AND SWIR SENSOR INCLUDING THE SAME

(71) Applicant: POSTECH RESEARCH AND BUSINESS DEVELOPMENT FOUNDATION, Pohang-si (KR)

(72) Inventors: Dae Sung CHUNG, Pohang-si (KR); Sangjun LEE, Pohang-si (KR)

(73) Assignee: POSTECH RESEARCH AND BUSINESS DEVELOPMENT FOUNDATION, Pohang-si (KR)

(21) Appl. No.: 18/731,817

(22) Filed: Jun. 3, 2024

(30) Foreign Application Priority Data
Jun. 8, 2023 (KR) 10-2023-0073801
May 8, 2024 (KR) 10-2024-0060543

(51) Int. Cl. H10K 39/32; H10K 71/12; H10K 85/10; H10K 85/60

(52) U.S. Cl. CPC H10K 39/32; H10K 71/12; H10K 85/113; H10K 85/611

(57) ABSTRACT

Provided is an organic photodiode for detecting SWIR, a method for manufacturing the same, and an SWIR sensor including the same, and more specifically, to an organic photodiode for SWIR detection including a first electrode, a second electrode, and a photoelectric conversion layer between the first and second electrodes. The photoelectric conversion layer includes a first photoelectric conversion layer and a second photoelectric conversion layer sequentially stacked, wherein the first photoelectric conversion layer includes a polymer represented by Formula 1, and an organic dopant represented by Formula 2.

### CROSS-REFERENCE TO RELATED APPLICATIONS

This U.S. non-provisional patent application claims priority under 35 U.S.C. § 119 of Korean Patent Application Nos. 10-2023-0073801, filed on Jun. 8, 2023, and 10-2024-0060543, filed on May 8, 2024, the entire contents of which are hereby incorporated by reference.

### BACKGROUND

The present disclosure herein relates to an organic photodiode for detecting SWIR, a method for manufacturing the same, and an SWIR sensor including the same.

This study was conducted with the support of the Samsung Future Technology Promotion Project (Project number: SRFC-TA1803-51).

Recently, photodetectors such as CMOS image sensors have been popularized and are being used in many fields as a replacement for film-type imaging devices. The photodetectors are not only utilized in place of the film-type imaging devices when photographing ordinary visible light, but are also significantly utilized when photographing invisible light such as ultraviolet rays, infrared rays, X-rays, and gamma rays.

A photodetector is a device that converts optical signals into electrical signals. The photodetector may include a photoelectric conversion layer. The photoelectric conversion layer may include a silicon-based photoelectric conversion layer, and an organic material-based photoelectric conversion layer. The organic material-based photoelectric conversion layer may include a mixture of a p-type semiconductor material and an n-type semiconductor material. The organic material-based photodetector has a problem of exhibiting high dark-current properties. If the organic material-based photodetector includes any one of a p-type semiconductor material and an n-type semiconductor material, there is a problem in that the photodiode has low external quantum efficiency.

### SUMMARY

The present disclosure provides an organic photodiode having excellent reactivity to SWIR.

The present disclosure also provides a method for manufacturing an organic photodiode having excellent reactivity to SWIR.

The present disclosure also provides an SWIR sensor including an organic photodiode having excellent reactivity to SWIR.

An embodiment of the inventive concept includes an organic photodiode for detecting SWIR, which includes a first electrode, a second electrode, and a photoelectric conversion layer between the first and second electrodes. In an embodiment, the photoelectric conversion layer may include a first photoelectric conversion layer and a second photoelectric conversion layer sequentially stacked, wherein the first photoelectric conversion layer may include a polymer represented by Formula 1 below, and an organic dopant represented by Formula 2 below.

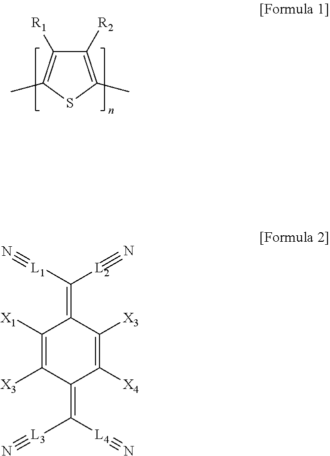

In Formula 1 above, R₁ and R₂ may be each independently hydrogen, or a substituted or unsubstituted C1-C20 alkyl group, and n may be an integer between 10 to 10,000, and in Formula 2 above, X₁, X₂, X₃, and X₄ may be each independently a halogen element selected from the group consisting of fluorine (F), chlorine (Cl), bromine (Br), and iodine (I), and L₁, L₂, L₃, and L₄ may be each independently a direct linkage, or a substituted or unsubstituted C1-C10 alkylene group.

In an embodiment of the inventive concept, an SWIR sensor includes a substrate, a first electrode on the substrate, a photoelectric conversion layer on the first electrode, and a second electrode on the photoelectric conversion layer. In an embodiment, the photoelectric conversion layer may include a polymer represented by Formula 1 below, and an organic dopant represented by Formula 2 below.

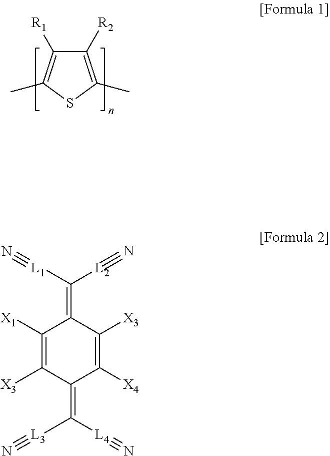

In Formula 1 above, R₁ and R₂ may be each independently hydrogen, or a substituted or unsubstituted C1-C20 alkyl group, and n may be an integer between 10 to 10,000, and in Formula 2 above, X₁, X₂, X₃, and X₄ may be each independently a halogen element selected from the group consisting of fluorine (F), chlorine (Cl), bromine (Br), and iodine (I), and L₁, L₂, L₃, and L₄ may be each independently a direct linkage, or a substituted or unsubstituted C1-C10 alkylene group.

In an embodiment of the inventive concept, a method for manufacturing a photoelectric conversion layer for detecting SWIR includes preparing a film including a polymer represented by Formula 1 below, coating a first doping solution on the film to perform a primary doping process on the polymer, and coating a second doping solution on the film to perform a secondary doping process on the polymer. In an embodiment, each of the first doping solution and the second doping solution may include an organic dopant represented by Formula 2 below, and a first solvent of the first doping solution and a second solvent of the second doping solution are different from each other.

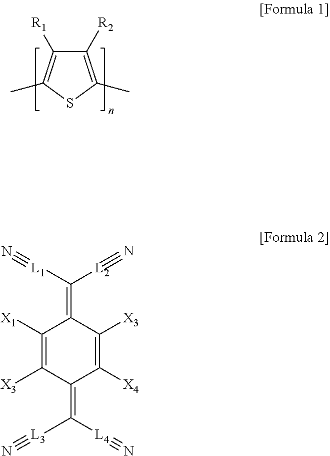

In Formula 1 above, R₁ and R₂ may be each independently hydrogen, or a substituted or unsubstituted C1-C20 alkyl group, and n may be an integer between 10 to 10,000, and in Formula 2 above, X₁, X₂, X₃, and X₄ may be each independently a halogen element selected from the group consisting of fluorine (F), chlorine (Cl), bromine (Br), and iodine (I), and L₁, L₂, L₃, and L₄ may be each independently a direct linkage, or a substituted or unsubstituted C1-C10 alkylene group.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a cross-sectional view schematically illustrating an organic photodiode for detecting SWIR according to an embodiment of the inventive concept;

FIG. 2 is a schematic diagram for explaining that an organic semiconductor material of the inventive concept has a polaron state due to an organic dopant;

FIG. 3 is a plan view schematically showing a first photoelectric conversion layer according to an embodiment of the inventive concept;

FIG. 4 is a plan view schematically showing a first photoelectric conversion layer according to a comparative example of the inventive concept;

FIG. 5 is a schematic diagram for explaining a free polaron and a bound polaron according to embodiments of the inventive concept;

FIG. 6 and FIG. 7 are schematic diagrams for explaining a mechanism in which a bound polaron is converted into a free polaron by SWIR light according to embodiments of the inventive concept;

FIG. 8 and FIG. 9 are schematic diagrams for explaining a method for manufacturing an organic photodiode for detecting SWIR according to embodiments of the inventive concept;

FIG. 10 is a graph showing d-spacing values according to changes in dopant concentration in a film of Example 1 and a film of Comparative Example 1;

FIG. 11A is a graph of χT according to a temperature T in the film of Example 1 and the film of Comparative Example 1;

FIG. 11B is a graph showing the density of total polarons and the density of bound polarons in the film of Example 1 and the film of Comparative Example 1;

FIG. 12A is a graph showing an EQE spectrum for an organic photodiode of Example 1 and an organic photodiode of Comparative Example 1;

FIG. 12B is a graph showing the responsivity for the organic photodiode of Example 1 and the organic photodiode of Comparative Example 1;

FIG. 12C shows the result of measuring J-V properties of the organic photodiode of Example 1 and the organic photodiode of Comparative Example 1; and

FIG. 13 is a cross-sectional view for explaining an SWIR sensor according to embodiments of the inventive concept.

### DETAILED DESCRIPTION

In order to facilitate sufficient understanding of the configuration and effects of the present invention, preferred embodiments of the inventive concept will be described with reference to the accompanying drawings. However, the present invention is not limited to the embodiments set forth below, and may be embodied in various forms and modified in many alternate forms. Rather, these embodiments are provided so that the disclosure of the present invention will be thorough and complete, and will fully convey the scope of the present invention to those skilled in the art to which the present invention pertains. Those skilled in the art will understand that the concepts of the present invention may be performed in any suitable environment.

The terms used herein are for the purpose of describing embodiments and are not intended to be limiting of the present invention. In the present specification, singular forms include plural forms unless the context clearly indicates otherwise. As used herein, the terms “comprises” and/or “comprising” are intended to be inclusive of the stated materials, steps, operations and/or devices, and do not exclude the possibility of the presence or the addition of one or more other materials, steps, operations, and/or devices.

In the present disclosure, when any film (or layer) is referred to as being on another film (or layer) or substrate, it means that the film may be directly formed on another film (or layer) or substrate, or that a third film (or layer) may be interposed therebetween.

Although the terms first, second, third, and the like are used in various embodiments of the present disclosure to describe various regions, films (or layers), and the like, these regions, films, and the like should not be limited by these terms. These terms are only used to distinguish any predetermined region or film (or layer) from another region or film (or layer). Thus, a film referred to as a first film in one embodiment may be referred to as a second film in another embodiment. Each embodiment described and exemplified herein also includes a complementary embodiment thereof. Like reference numerals refer to like elements throughout the specification.

In addition, embodiments described in the present specification will be described with reference to cross-sectional views and/or plan views which are ideal illustrations of the present invention. In the drawings, the thickness of films and regions are exaggerated for an effective description of technical contents. Accordingly, the shape of an exemplary drawing may be modified by manufacturing techniques and/or tolerances. The embodiments of the present invention are not limited to specific forms illustrated, but are intended to include changes in the form generated by a manufacturing process. For example, an etched region illustrated as a right angle may be rounded or may be in a shape having a predetermined curvature. Thus, the regions illustrated in the drawings have schematic properties, and the shapes of the regions illustrated in the drawings are intended to exemplify specific shapes of regions of a device and are not intended to limit the scope of the inventive concept.

In the present specification, an alkyl group may be a linear alkyl group, a branched alkyl group, or a cyclic alkyl group. The number of carbon atoms of the alkyl group is not particularly limited, but the alkyl group may be an alkyl group having 1 to 3 carbon atoms. Examples of the alkyl group may include a methyl group, an ethyl group, a propyl group, and the like, but are not limited to. An aromatic ring compound may be monocyclic or polycyclic. The number of carbon atoms of the aromatic ring compound may be 5 to 20, but is not limited thereto. Examples of the aromatic ring compound may include a phenyl group, a biphenyl group, a naphthyl group, and/or a fluorenyl group, but are not limited thereto.

In the present specification, a direct linkage may mean a single bond.

In the present specification, examples of a halogen element may include fluorine (F), chlorine (Cl), bromine (Br), and iodine (I), but are not limited thereto.

In the present specification, the “substituted or unsubstituted” may mean being substituted or unsubstituted with one or more substituents selected from the group consisting of a hydrogen atom, a deuterium atom, a halogen element, an ether group, a halogenated alkyl group, a halogenated alkoxy group, a halogenated ether group, an alkyl group, a cyano group, a cyano-substituted alkyl group, a cyano-substituted aryl group, a cyano-substituted aromatic ring group, and a hydrocarbon ring group. In addition, each of the substituents illustrated above may be substituted or unsubstituted. For example, a biphenyl group may be interpreted as an aryl group, and may be interpreted as a phenyl group substituted with a phenyl group.

Unless otherwise defined in Formulas of the present specification, if a chemical bond is not drawn at a position at which a chemical bond should be drawn, it may mean that a hydrogen atom is bonded at that position.

In the present specification, the same reference numerals may refer to the same components throughout the specification.

Short wavelength infrared (SWIR) may belong to wavelength range located between visible light and thermal radiation in an electromagnetic spectrum. The wavelength band of light of the SWIR may be 900 nm to 2,500 nm, 900 nm to 1,800 nm, or 1,200 nm to 1,800 nm. The SWIR may be located between mid-wavelength infrared (MWIR) and long-wavelength infrared (LWIR).

A typical organic photodiode, i.e., an organic semiconductor, usually uses a donor-asceptor (D-A) push-pull type copolymer to absorb low energy and narrow a wavelength range. The above-described method creates a composite state in which charges move within a molecule. Increasing the molecular weight of the polymer may lead to a narrower band gap, which may result in better absorption of light with a long wavelength.

Meanwhile, the above-described D-A type copolymer has a problem in that it is difficult to absorb an SWIR region. Some previous studies have reported a copolymer having extended absorption up to 1.5 μm, but in practice, absorption occurs only at 1.0 μm to 1.1 μm, and wavelengths beyond that are rarely absorbed. As a result, it is considered to be difficult for an organic semiconductor to detect SWIR light having a wavelength of 1.5 μm or greater.

Meanwhile, a doped organic semiconductor may absorb SWIR. However, a doped polymer has excessively high conductivity. Due to a high dark current caused by high conductivity, it is difficult to utilize the doped organic semiconductor as a sensor for detecting SWIR.

Hereinafter, an organic photodiode for detecting SWIR according to the inventive concept, and an SWIR sensor including the same will be described.

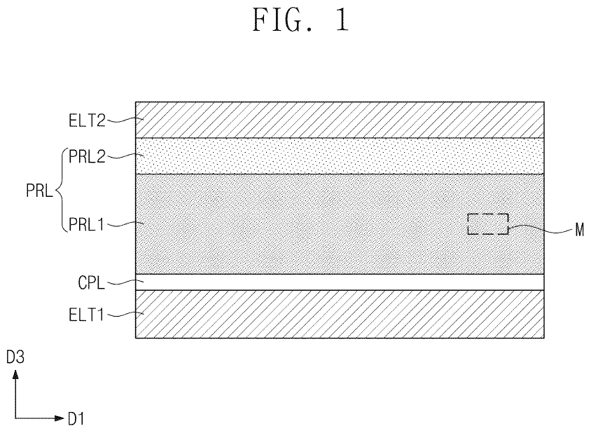

FIG. 1 is a cross-sectional view schematically illustrating an organic photodiode for detecting SWIR according to an embodiment of the inventive concept. Referring to FIG. 1, the organic photodiode may include a first electrode ELT1, a conductive polymer layer CPL, a photoelectric conversion layer PRL, and a second electrode ELT2, which are sequentially stacked. Although not illustrated, the organic photodiode may further include a substrate provided below the first electrode ELT1. As an example, a substrate may include a semiconductor substrate (e.g., a silicon substrate), an organic substrate, or an inorganic substrate (e.g., a glass substrate). However, the material of the substrate is not limited thereto.

The first electrode ELT1 may include a metal, doped polysilicon, or a conductive polymer. The first electrode ELT1 may function as a lower electrode of the organic photodiode. The second electrode ELT2 may be disposed on the first electrode ELT1. The second electrode ELT2 may be spaced apart from a first electrode 210. The second electrode ELT2 may function as an upper electrode of the organic photodiode.

A voltage applied to the second electrode ELT2 may be different from a voltage applied to the first electrode ELT1. Any one of the first electrode ELT1 and the second electrode ELT2 may be an anode, and the other thereof may be a cathode. At least one of the first electrode ELT1 and the second electrode ELT2 may be a transparent electrode. For example, if light is incident through the first electrode ELT1, the first electrode ELT1 may be transparent. If light is incident through the second electrode ELT2, the second electrode ELT2 may be transparent.

The photoelectric conversion layer PRL may be disposed between the first electrode ELT1 and the second electrode ELT2. For example, the photoelectric conversion layer PRL may have a first surface and a second surface which face each other. The first electrode ELT1 may be disposed on the first surface of the photoelectric conversion layer PRL, and the second electrode ELT2 may be disposed on the second surface of the photoelectric conversion layer PRL.

According to an embodiment of the present invention, the conductive polymer layer CPL may be interposed between the photoelectric conversion layer PRL and the first electrode ELT1.

The conductive polymer layer CPL may perform a function of transporting charges between the first electrode ELT1 and the photoelectric conversion layer PRL.

As an example, the conductive polymer layer CPL may be formed of a transparent material together with the first electrode ELT1. Thus, light may pass through the first electrode ELT1 and the conductive polymer layer CPL to be incident on the photoelectric conversion layer PRL. The conductive polymer layer CPL may function as an adhesive layer for bonding the first electrode ELT1 and the photoelectric conversion layer PRL to each other.

The conductive polymer layer CPL may include a conductive polymer. For example, the conductive polymer layer CPL may include at least one selected from the group consisting of PEDOT:PSS, poly(3-hexylthiophene) (P3HT), and polyfluorenes.

The photoelectric conversion layer PRL may include an organic semiconductor material. The organic semiconductor material may be an organic polymer. For example, the organic semiconductor material according to the present embodiments may include polythiophene and/or a derivative thereof. The photoelectric conversion layer PRL may further include an organic dopant doped in the organic semiconductor material.

Specifically, the photoelectric conversion layer PRL may include a first photoelectric conversion layer PRL1 and a second photoelectric conversion layer PRL2. The first and second photoelectric conversion layers PRL1 and PRL2 may be sequentially stacked. The first photoelectric conversion layer PRL1 may be adjacent to the first electrode ELT1, and the second photoelectric conversion layer PRL2 may be adjacent to the second electrode ELT2.

The first photoelectric conversion layer PRL1 may include an organic dopant and an organic semiconductor material, that is, a conductive polymer. The second photoelectric conversion layer PRL2 may include an organic semiconductor material, that is, a conductive polymer. The second photoelectric conversion layer PRL2 may be excluded from an organic dopant. That is, the second photoelectric conversion layer PRL2 may be an undoped layer.

The organic semiconductor material in the photoelectric conversion layer PRL may include a polymer represented by Formula 1 below.

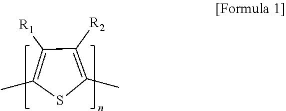

In Formula 1, R₁ and R₂ may each independently be hydrogen, or a substituted or unsubstituted C1-C20 alkyl group. n may be an integer between 10 to 10,000. The polymer of Formula 1 according to the present embodiment may have a molecular weight of 10,000 to 100,000. The molecular weight may refer to a weight average molecular weight.

In an embodiment, the organic semiconductor material in the photoelectric conversion layer PRL may include poly(3-hexylthiophene (P3HT).

The first photoelectric conversion layer PRL1 may further include an organic dopant as well as the above-described organic semiconductor material. The organic dopant may be doped in the organic semiconductor material. The organic dopant may include a compound represented by Formula 2 below.

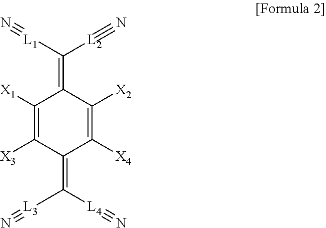

In Formula 2, X₁, X₂, X₃, and X₄ may each independently be a halogen element selected from the group consisting of fluorine (F), chlorine (Cl), bromine (Br), and iodine (I). L₁, L₂, L₃, and L₄ may each independently be a direct linkage, or a substituted or unsubstituted C1-C10 an alkylene group.

In an embodiment, the organic dopant may include 2,3,5,6-tetrafluoro-7,7,8,8-tetracyanoquinodimethane (F4TCNQ).

In an embodiment, the concentration of the organic dopant in the first photoelectric conversion layer PRL1 may be 1 ppm to 100 ppm.

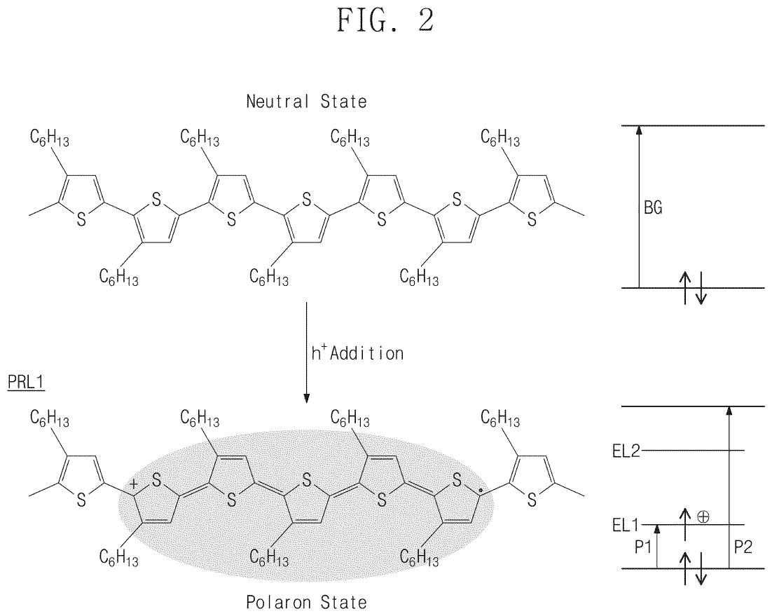

FIG. 2 is a schematic diagram for explaining that an organic semiconductor material of the inventive concept has a polaron state due to an organic dopant. Referring to FIG. 2, the organic semiconductor material of the first photoelectric conversion layer PRL1 may have a polaron state due to the organic dopant.

Specifically, the organic dopant of Formula 2 may be doped to the polymer of Formula 1 to generate anions. Electrons in the polymer of Formula 1 may be transferred to the organic dopant to generate an anion dopant. Electrons in the polymer of Formula 1 may be transferred to the organic dopant to generate positive charges in a polymer chain. The positive charges may cause structural deformation in the polymer chain to create a quinoid structure in the polymer. In other words, the organic dopant may transform at least one of aromatic rings in the polymer into a quinoid ring.

The quinoid structure and a radical cation may constitute a positive polaron. The positive polaron may include a singly occupied first energy level EL1 that is higher than a valence band edge and an unoccupied second energy level EL2 that is lower than a conduction band edge.

The positive polaron may cause strong sub-gap absorption in an SWIR region P1 and an NIR region P2 respectively by the above-described sub-gaps EL1 and EL2. The organic photodiode according to the present invention may function as a photodiode capable of effectively detecting SWIR by utilizing properties in which a polaron in the first photoelectric conversion layer PRL1 is capable of strongly absorbing the SWIR region P1.

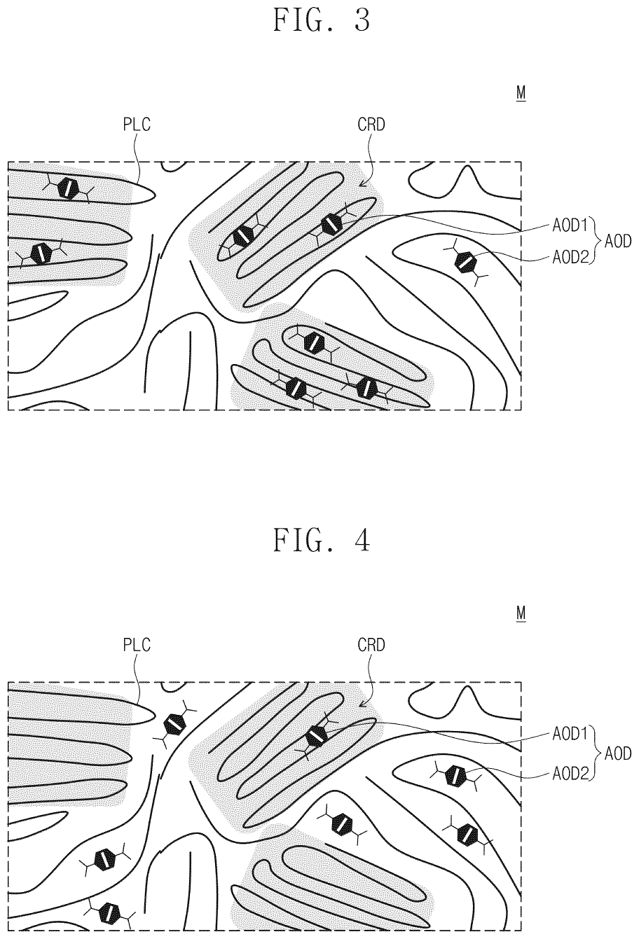

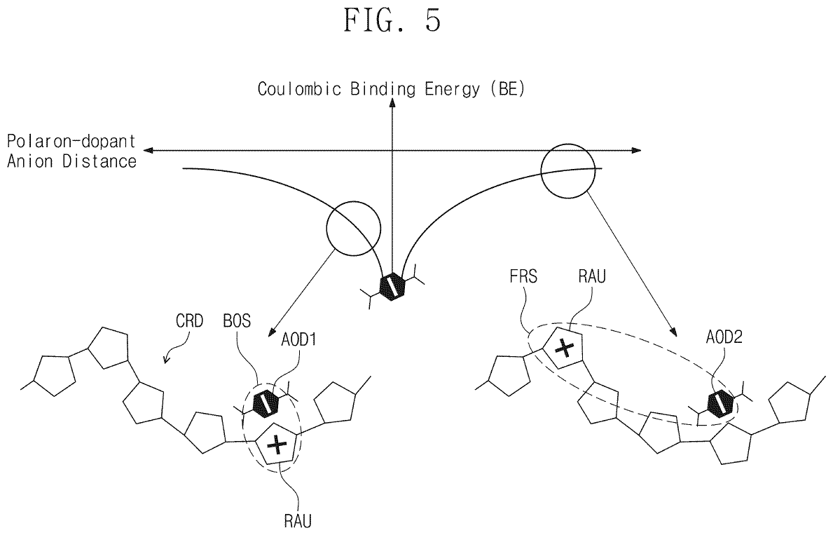

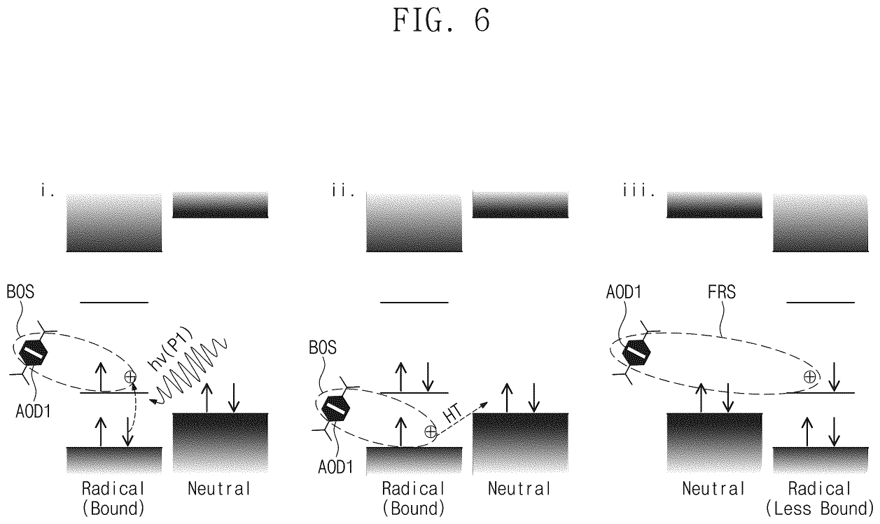

FIG. 3 is a plan view schematically showing a first photoelectric conversion layer according to an embodiment of the inventive concept. FIG. 4 is a plan view schematically showing a first photoelectric conversion layer according to a comparative example of the inventive concept. FIG. 5 is a schematic diagram for explaining a free polaron and a bound polaron according to embodiments of the inventive concept.

Referring to FIG. 3, the first conversion unit PRL1 may include a polymer chain layer PLC and organic dopants AOD. The polymer chain PLC may include a crystallized crystalline domain CRD.

The organic dopants AOD may include a first organic dopant AOD1 located in the crystalline domain CRD and a second organic dopant AOD2 located in a region other than the crystalline domain CRD. In an embodiment, the second organic dopant AOD2 may be located in an amorphous domain of the polymer.

Referring to FIG. 3 and FIG. 5, the first organic dopant AOD1 may be located in close proximity to a radical unit RAU in the crystalline domain CRD. Between the first organic dopant AOD1 and the radical unit RAU, a relatively strong Coulomb bonding energy BE may be generated. Thus, the first organic dopant AOD1 may form a bound polaron BOS, which is fixed inside the polymer chain PLC without being able to move freely.

The second organic dopant AOD2 may be located far apart from the radical unit RAU within the crystalline domain CRD. Between the second organic dopant AOD2 and the radical unit RAU, a relatively weak Coulomb bonding energy BE may be generated. Thus, the second organic dopant AOD2 may form a free polaron FRS, which is able to move freely inside the polymer chain PLC.

The bound polaron BOS is not able to move freely, and thus, may not have a significant impact on the conductivity of the first photoelectric conversion layer PRL1. However, the free polaron FRS is able to move freely, and thus, may have a significant impact on the conductivity of the first photoelectric conversion layer PRL1.

In the first photoelectric conversion layer PRL1 according to the present embodiment, the ratio of bound polarons to the total polarons may be relatively large. Specifically, the ratio of the density of the bound polarons to the density of the total polarons may be 10% to 50%, or 20% to 40%. If the ratio of the bound polarons is within the range described above, dark currents caused by the first photoelectric conversion layer PRL1 may be reduced, and at the same time, the responsiveness to SWIR may be improved.

Referring to FIG. 4, the ratio of the first organic dopant AOD1 in the first photoelectric conversion layer PRL1 according to a comparative example of the present invention may be smaller than the ratio of the first organic dopant AOD1 in the first photoelectric conversion layer PRL1 of the example shown in FIG. 3. That is, the first photoelectric conversion layer PRL1 of the comparative example may have a relatively low ration of bound polarons. Thus, the first photoelectric conversion layer PRL1 of the comparative example may have high conductivity due to doping, which may cause a problem of greatly generating dark currents. The dark current may cause a major problem in a photodiode for detecting SWIR.

Referring back to FIG. 3, the first photoelectric conversion layer PRL1 according to the present embodiment has a high ratio of bound polarons, and thus, is capable of suppressing an increase in conductivity due to doping. Thus, it is possible to prevent the problem of greatly generating dark currents. The first photoelectric conversion layer PRL1 according to the present embodiment may be effectively used in a photodiode for detecting SWIR.

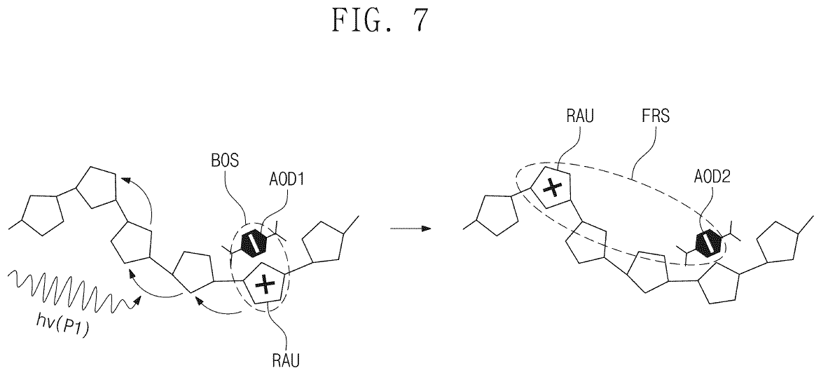

FIG. 6 and FIG. 7 are schematic diagrams for explaining a mechanism in which a bound polaron is converted into a free polaron by SWIR light according to embodiments of the inventive concept.

Referring to FIG. 6 and FIG. 7, light of the SWIR region P1 may be incident on the first photoelectric conversion layer PRL1. The bound polaron BOS may be excited by the incident light. Specifically, an electron at a valence band edge of a radical unit may be excited by incident light to a first energy level EL1, (see FIG. 2). Thereafter, due to an energy offset between a valence band maximum and an external bias, a hole may move from the radical unit to an adjacent neutral unit.

The adjacent neutral unit may be converted into a radical unit, and the radical unit may be converted into a neutral unit. Meanwhile, the location of the first organic dopant AOD1 may be fixed as it is. As a result, when light of the SWIR region P1 is irradiated, the radical unit may gradually move away from the first organic dopant AOD1. Thus, the bound polaron BOS may be converted into the free polaron FRS. In other words, if the first photoelectric conversion layer PRL1 according to the present invention is irradiated with light of the SWIR region P1, the bound polaron BOS within the first photoelectric conversion layer PRL1 may be converted into the free polaron FRS.

The free polaron FRS serves as a free hole to improve the photoconductivity of the organic photodiode. Since the free polaron FRS is generated, the response to light of the SWIR region P1 may become stronger.

Referring back to FIG. 1, if SWIR is not incident, the organic photodiode according to the present invention may have low conductivity due to a bound polaron even if the first photoelectric conversion layer PRL1 is a doping layer. Thus, it is possible to prevent the generation of dark currents.

Meanwhile, if SWIR is incident on the organic photodiode, the first photoelectric conversion layer PRL1 may convert a bound polaron into a free polaron in response to the SWIR. Thus, free charges are generated in the first photoelectric conversion layer (PRL1), and current can flow in the organic photodiode composed of the first and second photoelectric conversion layers (PRL1 and PRL2).

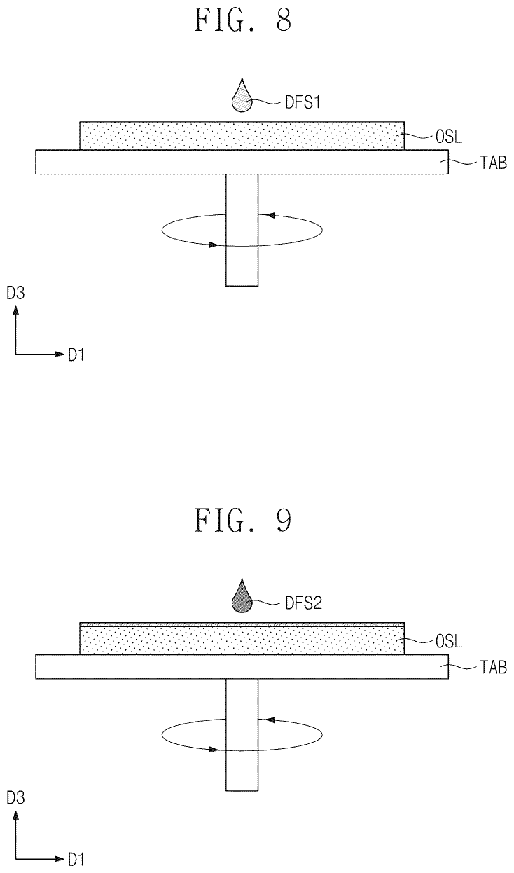

FIG. 8 and FIG. 9 are schematic diagrams for explaining a method for manufacturing an organic photodiode for detecting SWIR according to embodiments of the inventive concept.

Referring to FIG. 8, an organic semiconductor film OSL may be provided on a table TAB. In an embodiment, the organic semiconductor film OSL may include a polymer represented by Formula 1 described above. For example, the organic semiconductor film OSL may include P3HT.

Primary doping may be performed on the organic semiconductor film OSL. By rotating the table TAB, a first doping solution DFS1 may be provided on the organic semiconductor film OSL. The first doping solution DFS1 may include an organic dopant represented by Formula 2 described above, and a first solvent. For example, the first solvent may include acetonitrile. As the first doping solution DFS1 is coated on the organic semiconductor film OSL, the organic dopant may be doped into the polymer in the organic semiconductor film OSL.

In an embodiment, the concentration of organic dopant in the first doping solution DFS1 may be 0.5 mg/mL to 5 mg/mL, or 0.5 mg/mL to 2 mg/mL.

As a result of the above-described primary doping process, in the organic semiconductor film OSL, the ratio of the first organic dopant AOD1 located in the crystalline domain CRD may be relatively small as illustrated in FIG. 4. The ratio of the secondary organic dopant AOD2 located in a region other than the crystalline domain CRD may be relatively large.

Referring to FIG. 9, secondary doping may be performed on the organic semiconductor film OSL. By rotating the table TAB, a second doping solution DFS2 may be provided on the organic semiconductor film OSL. The second doping solution DFS2 may include an organic dopant represented by Formula 2 described above, and a second solvent.

The second solvent may be different from the first solvent. The second solvent is capable of swelling the polymer in the organic semiconductor film OSL. If the polymer is swollen by the second solvent, the organic dopant may easily penetrate into the crystalline domain CRD. For example, the second solvent may include chlorobenzene.

In an embodiment, the concentration of organic dopant in the second doping solution DFS2 may be 0.5 mg/mL to 5 mg/mL, or 0.5 mg/mL to 2 mg/mL.

As a result of the above-described secondary doping process, in the organic semiconductor film OSL, the ratio of the first organic dopant AOD1 located in the crystalline domain CRD may become relatively large as illustrated in FIG. 3. The ratio of the secondary organic dopant AOD2 located in a region other than the crystalline domain CRD may become relatively small.

As a result of the above-described secondary doping process, the organic semiconductor layer OSL may be used as the first photoelectric conversion layer PRL1 described above with reference to FIG. 1. By the secondary doping process, the first photoelectric conversion layer PRL1 prepared by the method according to the present invention may have a relatively high ratio of bound polarons. Thus, compared to an organic semiconductor film on which only the first doping process was performed, the first photoelectric conversion layer PRL1 according to the present invention may have low electrical conductivity in a state in which SWIR light is not incident.

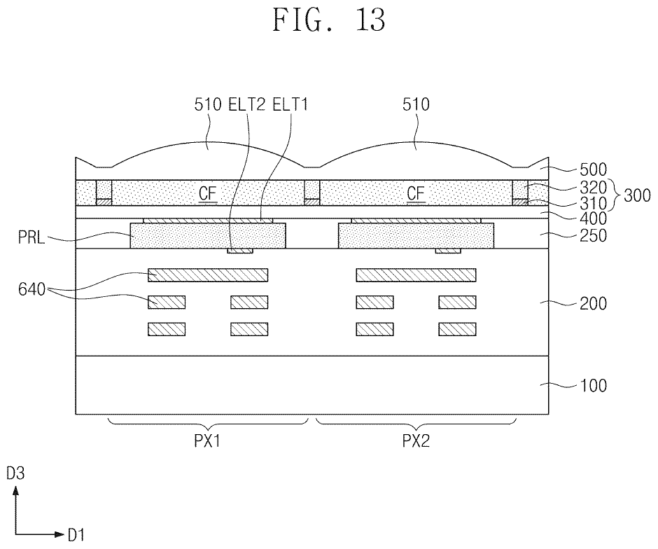

FIG. 13 is a diagram for explaining an SWIR sensor according to embodiments of the inventive concept. Referring to FIG. 13, the SWIR sensor may include a substrate 100, a wiring layer 200, first electrodes ELT1, photoelectric conversion layers PRL, second electrodes ELT 2, a protective layer 400, and a micro-lens layer 500.

The substrate 100 may be a semiconductor substrate. For example, the substrate 100 may include silicon or silicon-germanium. The substrate 100 may include pixel regions. The pixel regions may be arranged in a two-dimensional form. In an embodiment, the pixel regions of the substrate 100 may include a first pixel region PX1 and a second pixel region PX2.

In an embodiment of the present invention, the substrate 100 may be a substrate of a circuit chip. Specifically, an integrated circuit may be provided on the substrate 100. The integrated circuit on the substrate 100 may include logic circuits, memory circuits, or a combination thereof. The integrated circuit on the substrate 100 may include, for example, transistors. The wiring layer 200 to be described later may be electrically connected to the integrated circuit on the substrate 100. The wiring layer 200 may electrically connect the integrated circuit on the substrate 100 and the photoelectric conversion layers PRL to each other.

The wiring layer 200 may be disposed on the substrate 100. The wiring layer 200 may include an insulation layer and stacked wiring patterns 640. The insulation layer may be a single layer or a multi-layer. The wiring patterns 640 may be provided in the insulation layer. The wiring patterns 640 may include a conductive material such as metal.

The second electrodes ELT2 may be provided in the wiring layer 200. The second electrodes ELT2 may be electrically connected to the wiring patterns 640, respectively. In an embodiment, the second electrodes ELT2 may be exposed through an upper surface of the wiring layer 200. The second electrodes ELT2 may be provided in the first pixel region PX2 and the second pixel region PX2, respectively. The second electrodes ELT2 may each be pixel electrodes.

An insulation layer 250 may be provided on the wiring layer 200. The photoelectric conversion layers PRL may be provided in the insulation layer 250. The photoelectric conversion layers PRL may be provided in the first pixel region PX1 and the second pixel region PX2, respectively. Each of the photoelectric conversion layers PRL may be substantially the same as the photoelectric conversion layer PRL described with reference to FIG. 1. The photoelectric conversion layer PRL may include an organic semiconductor material. Each of the photoelectric conversion layers PRL can react to incident SWIR light.

The first electrodes ELT1 may be disposed on the photoelectric conversion layers PRL, respectively. Each of the first electrodes ELT1 may be electrically connected to a corresponding photoelectric conversion layer PRL. A voltage applied to the first electrodes ELT1 may be different from a voltage applied to the second electrodes ELT2. If the second electrodes ELT2 are anodes, the first electrodes ELT1 may be cathodes. If the second electrodes ELT2 are cathodes, the first electrodes ELT1 may be anodes. The first electrodes ELT1 may be transparent electrodes.

A protective layer 400 may be provided on the insulation layer 250. The protective layer 400 may be provided on a plurality of first electrodes ELT1. The protective layer 400 may have insulation properties. The protective layer 400 may include, for example, an organic material such as a polymer. The protective layer 400 may be transparent.

Color filters CF and a fence pattern 300 may be provided on the protective layer 400. In an embodiment, the fence pattern 300 may be interposed between two adjacent color filters CF to separate the color filters CF from each other. For example, the color filters CF may be physically and optically separated from each other by the fence pattern 300.

In an embodiment, the fence pattern 300 may have a grid shape. When viewed in a plan view, the fence pattern 300 may surround each of the first and second pixel regions PX1 and PX2. The fence pattern 300 may surround each of the color filters CF.

The fence pattern 300 may include a first fence pattern 310 and a second fence pattern 320. The first fence pattern 310 may be disposed between the insulation layer 250 and the second fence pattern 320. The first fence pattern 310 may include a conductive material such as a metal and/or a metal nitride. For example, the first fence pattern 310 may include titanium and/or titanium nitride.

The second fence pattern 320 may be disposed on the first fence pattern 310. The second fence pattern 320 may include a material different from that of the first fence pattern 310. The second fence pattern 320 may include an organic material. The second fence pattern 320 includes a low refractive material, and may have insulation properties.

The micro-lens layer 500 may be provided on the color filters CF. The micro-lens layer 500 may include a plurality of convex micro-lenses 510. In an embodiment, the micro-lenses 510 may be provided at positions corresponding to the photoelectric conversion layers PRL, respectively. In an embodiment, the micro-lenses 510 may be provided on the color filters CF, respectively, and may correspond to the color filters CF, respectively.

The micro-lenses 510 may be arranged in a two-dimensional array when viewed in a plan view. Each of the micro-lenses 510 may have a protruding shape. Each of the micro-lenses 510 may have a hemispherical cross-section. The micro-lenses 510 may concentrate incident light.

The micro-lens layer 500 is transparent, and thus, may transmit light. The micro-lens layer 500 may include an organic material such as a polymer. For example, the micro-lens layer 500 may include a photoresist material or a thermosetting resin.

The organic photodiode for detecting SWIR according to the present invention may be used in an SWIR camera. The SWIR camera may provide thermal imaging which can be used even at night.

The organic photodiode for detecting SWIR according to the present invention may be used as a sensor for detecting the properties of a material. For example, an SWIR sensor may detect a defective material or a material containing a specific chemical substance. The SWIR sensor may be used to evaluate the health status of plants.

The SWIR sensor may be used to detect defects and inspect quality in a semiconductor chip manufacturing process. This may help improve the efficiency of a semiconductor process and improve the reliability of a semiconductor device.

Hereinafter, the present invention will be described in more detail with reference to examples. However, the following examples are merely illustrative of the present invention, and are not intended to limit the scope of the present invention.

### Example 1: Preparation of Double-Doped Film

A P3HT film was fixed to a table of spin coating equipment. The table is rotated with a spinning rate of 1,000 rpm. The P3HT film was heat-treated at 150° C. for 10 μminutes.

A first doping solution (F4TCNQ and acetonitrile) was prepared. The concentration of a dopant (F4TCNQ) of the first doping solution was 0.1 mg/mL. The first doping solution was provided on the P3HT film (primary doping).

A second doping solution (F4TCNQ and chlorobenzene) was prepared. The concentration of a dopant (F4TCNQ) of the second doping solution was 1 mg/mL. The second doping solution was provided on the P3HT film after the primary doping (secondary doping).

### Comparative Example 1: Preparation of Single-Doped Film

The second doping process was omitted, and only the first doping process was performed on a P3HT film. At this time, the concentration of the doping solution was 1 mg/mL.

### Comparative Example 2: Preparation of Undoped Film

An undoped P3HT film without a doping process was prepared.

### Organic Photodiode

An organic photodiode was manufactured using the film of Example 1 and the film of Comparative Example 1. Specifically, a PEDOT:PSS solution was spin-coated on a patterned ITO substrate. Heat treatment was performed at 140° C. for 20 minutes on the coated PEDOT:PSS solution to form a PEDOT:PSS intermediate film. A doped film (Example 1 and Comparative Example 1) was provided on the PEDOT:PSS intermediate film. An undoped P3HT film was formed on the doped film. The undoped P3HT film was formed using spin coating.

An aluminum electrode was formed on the undoped P3HT film. The aluminum electrode was formed using thermal evaporation. The area of an active region of the manufactured SWIR organic photodiode was about 0.09 cm².

### Experimental Example 1: Evaluation of Effect of Doping Solvent on Location of Dopant

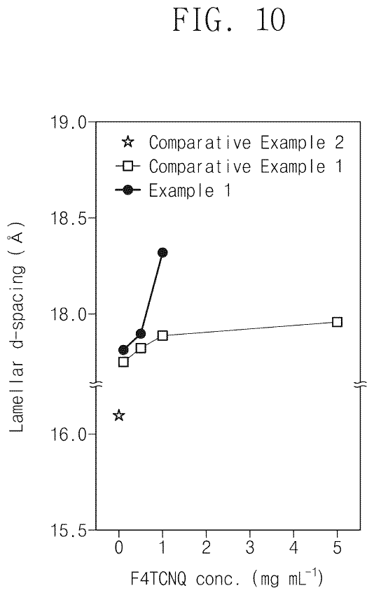

For the film of Example 1 and the film of Comparative Example 1, a d-spacing value according to the change in dopant concentration was calculated, and the results are shown in FIG. 10. The d-Spacing value was calculated using 2D-GIXD measurement. The 2D-GIXD measurement was conducted in Pohang Accelerator Laboratory, Republic of Korea.

Referring to FIG. 10, when chlorobenzene is used as a doping solvent as in Example 1, it can be confirmed that the d-spacing value significantly changes from 16.14 Å to 18.32 Å. On the other hand, when only the primary doping is performed using acetonitrile as a doping solvent as in Comparative Example 1, the d-spacing value hardly changes.

When doping is performed using chlorobenzene as in Example 1, it can be confirmed that the F4TCNQ dopant can effectively penetrate into the crystalline domain of the polymer. On the other hand, when doping is performed using only the acetonitrile as in Comparative Example 1, it can be confirmed that the F4TCNQ dopant is mainly located in the amorphous domain. This confirms that chlorobenzene allows a P3HT polymer to swell, thereby securing a space for a dopant to penetrate into a crystalline domain of the polymer.

### Experimental Example 2: Polaron Behavior Properties

For the film of Example 1 and the film of Comparative Example 1, ESR measurement was performed according to temperature. Using a reference sample CuSO₄·5H₂O, spin susceptibility χ was calculated from the ESR measurement results.

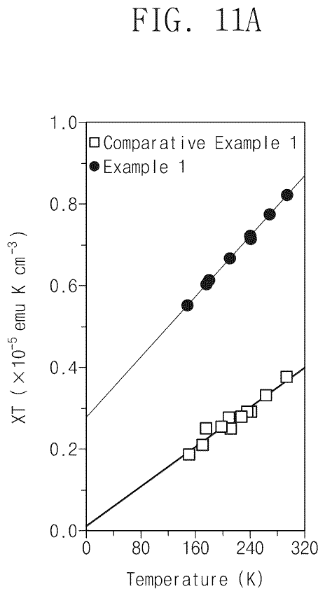

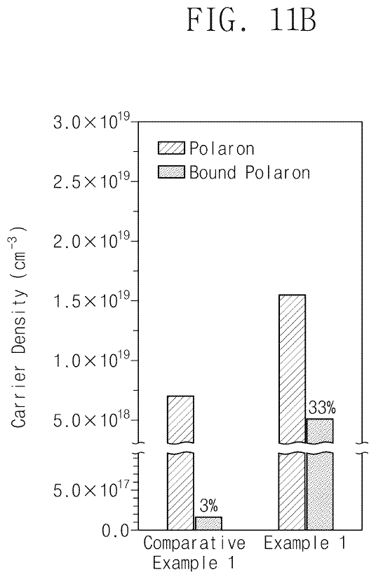

A graph of χT according to a temperature T is shown in FIG. 11A. Referring to FIG. 11A, the degree of localization of polarons for the film of Example 1 and the film of Comparative Example 1 can be confirmed.

A Curie constant of Example 1 and a Curie constant of Comparative Example 1 were obtained through the slope of each graph. It can be confirmed that the Curie constant (C) of Example 1 is significantly larger than the Curie constant (C) of Comparative Example 1.

Using Equation 1 below, the density of bound polarons n_{bound polaron} was calculated.

$$C = {n}_{bound polaron} \cdot {{μ}_{B}}^{2} \cdot {{k}_{B}}^{- 1} \qquad [ Equation 1 ]$$

μB is Bohr magneton.

For the film of Example 1 and the film of Comparative Example 1, the density of total polarons and the density of bound polarons were calculated, and the results are shown in FIG. 11B.

Referring to FIG. 11B, it was confirmed that the film of Comparative Example 1 had a very small ratio of the bound polarons to the total polarons, which was about 3%. It was confirmed that the film of Example 1 had a relatively large ratio of the bound polarons to the total polarons, which was about 33%.

### Experimental Example 3: Properties of Organic Photodiode

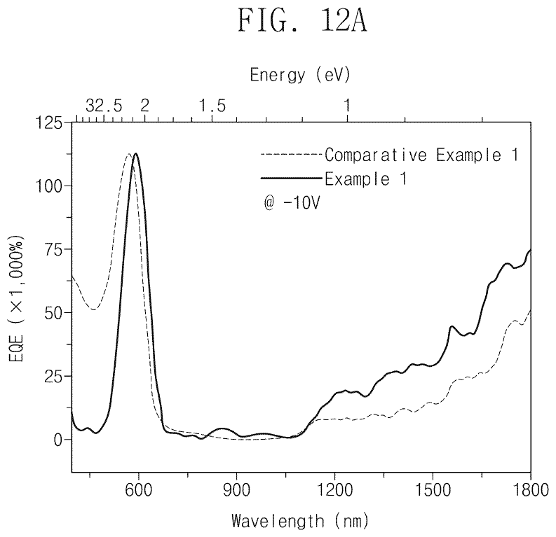

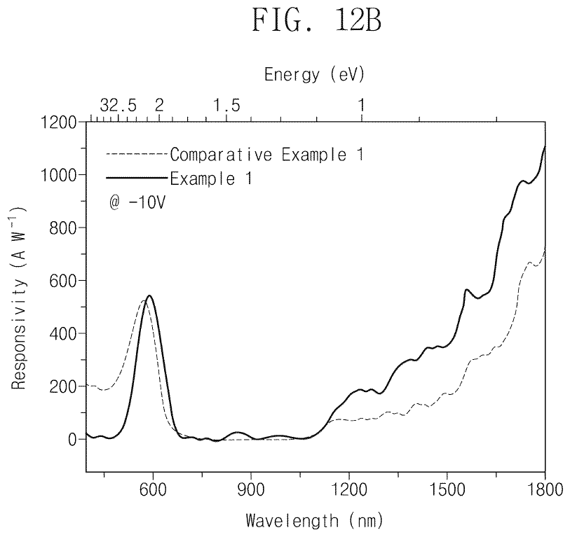

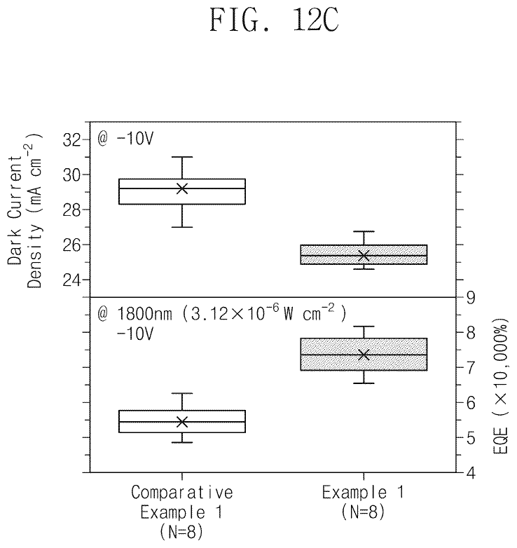

For the organic photodiode of Example 1 and the organic photodiode of Comparative Example 1, an EQE spectrum and responsivity were measured, and are respectively shown in FIG. 12A and FIG. 12B. For the organic photodiode of Example 1 and the organic photodiode of Comparative Example 1, J-V properties were measured, and the results are shown in FIG. 12C.

The EQE spectrum and the J-V properties were measured using equipment in which a Keithley 2450 SourceMeter and a 150 W QTH lamp are coupled to an Oriel Cornerstone monochromator. The experimental settings were controlled with the LabView program. The LDR of the device was determined using the same EQE/J-V measurement settings, and the intensity of light (3.12×10⁻⁶ W cm⁻² to 3.12×10⁻⁹ W cm⁻²) was adjusted using various neutral-density filters.

Referring to FIG. 12A and FIG. 12B, it can be confirmed that both the organic photodiode of Example 1 and the organic photodiode of Comparative Example 1 had a photoresponse to SWIR between 1,200 nm and 1,800 nm.

Specifically, it can be confirmed that both devices have similar EQE values in the visible range. However, it can be confirmed that in the SWIR range (1,200 nm to 1,800 nm), the EQE value of the organic photodiode of Example 1 is greater than the EQE value of the organic photodiode of Comparative Example 1. It can be confirmed that in the SWIR range (1,200 nm to 1,800 nm), the responsivity of the organic photodiode of Example 1 is greater than the responsivity of the organic photodiode of Comparative Example 1.

For example, at 1800 nm, the EQE value of the organic photodiode of Example 1 was 77% and the responsivity was 1,120 AW⁻¹. This was 150% greater than that of the organic photodiode of Comparative Example 1.

In conclusion, it can be confirmed that the organic photodiode according to the embodiments of the present invention has high photoresponsivity and high photoefficiency with respect to SWIR.

Referring to FIG. 12C, it can be seen that the dark current of the organic photodiode of Example 1 is measured much lower than the dark current of the organic photodiode of Comparative Example 1. This is because the first photoelectric conversion layer PRL1 of the organic photodiode according to the present invention has relatively small conductivity due to a high ratio of bound polarons.

An organic semiconductor according to the present invention has a relatively large ratio of bound polarons, and thus, has excellent responsiveness to SWIR, and at the same time, is capable of significantly reducing dark currents. The organic semiconductor according to the present invention may be utilized as an organic photodiode for detecting SWIR. An organic photodiode of the present invention may have high external quantum efficiency and high responsivity in an SWIR region.

What is claimed is:

1. An organic photodiode for detecting SWIR comprising:
a first electrode; a second electrode; and
a photoelectric conversion layer between the first and second electrodes,
wherein the photoelectric conversion layer includes a first photoelectric conversion layer and a second photoelectric conversion layer that are sequentially stacked,
wherein the first photoelectric conversion layer includes a polymer represented by Formula 1 below, and an organic dopant represented by Formula 2 below: 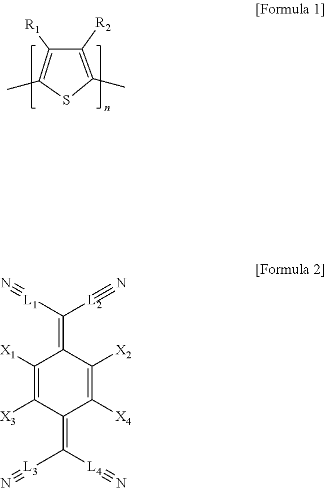
wherein in Formula 1 above, R₁ and R₂ are each independently hydrogen, or a substituted or unsubstituted C1-C20 alkyl group, and n is an integer between 10 to 10,000, and
wherein in Formula 2 above, X₁, X₂, X₃, and X₄ are each independently a halogen element selected from the group consisting of fluorine (F), chlorine (Cl), bromine (Br), and iodine (I), and L₁, L₂, L₃, and L₄ are each independently a direct linkage, or a substituted or unsubstituted C1-C10 alkylene group.

2. The organic photodiode of claim 1, wherein the organic dopant forms a bound polaron and a free polaron in the first photoelectric conversion layer, and
wherein the ratio of the density of the bound polarons to the density of the total polarons in the first photoelectric conversion layer is about 10% to about 50%.

3. The organic photodiode of claim 2, wherein, when SWIR light is incident on the first photoelectric conversion layer, the bound polaron is converted into the free polaron in response to the SWIR light.

4. The organic photodiode of claim 2, wherein the organic dopant comprises a first organic dopant and a second organic dopant,
wherein the first organic dopant is located in a crystalline domain of the polymer,
the second organic dopant is located in an amorphous domain of the polymer, the first organic dopant forms the bound polaron, and
the second organic dopant forms the free polaron.

5. The organic photodiode of claim 1, wherein the second photoelectric conversion layer comprises the polymer, and
wherein the second photoelectric conversion layer is an undoped layer.

6. The organic photodiode of claim 1, wherein the polymer comprises poly(3-hexylthiophene) (P3HT).

7. The organic photodiode of claim 1, wherein the organic dopant comprises 2,3,5,6-tetrafluoro-7,7,8,8-tetracyanoquinodimethane (F4TCNQ).

8. The organic photodiode of claim 1, wherein the polymer of the first photoelectric conversion layer comprises a radical cation having a quinoid structure, and
wherein the organic dopant is an anionic dopant.

9. The organic photodiode of claim 8, wherein the radical cation having the quinoid structure constitutes a positive polaron.

10. The organic photodiode of claim 1, further comprising a conductive polymer layer between the first electrode and the first photoelectric conversion layer.

11. An SWIR sensor comprising:
a substrate;
a first electrode on the substrate;
a photoelectric conversion layer on the first electrode; and
a second electrode on the photoelectric conversion layer,
wherein the photoelectric conversion layer includes a polymer represented by Formula 1 below, and an organic dopant represented by Formula 2 below: 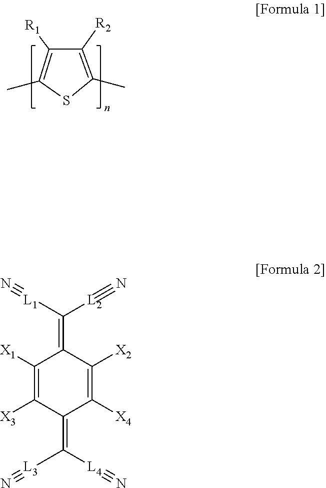
wherein in Formula 1 above, R₁ and R₂ are each independently hydrogen, or a substituted or unsubstituted C1-C20 alkyl group, and n is an integer between 10 to 10,000, and
wherein in Formula 2 above, X₁, X₂, X₃, and X₄ are each independently a halogen element selected from the group consisting of fluorine (F), chlorine (Cl), bromine (Br), and iodine (I), and L₁, L₂, L₃, and L₄ are each independently a direct linkage, or a substituted or unsubstituted C1-C10 alkylene group.

12. The SWIR sensor of claim 11, wherein the photoelectric conversion layer comprises:
a first photoelectric conversion layer including the polymer and the organic dopant; and
a second photoelectric conversion layer including the polymer,
wherein the second photoelectric conversion layer is an undoped layer.

13. The SWIR sensor of claim 11, wherein:
the polymer comprises a radical cation having a quinoid structure; and
the organic dopant is an anionic dopant.

14. The SWIR sensor of claim 11, further comprising:
a color filter on the second electrode; and
micro-lenses on the color filter.

15. The SWIR sensor of claim 11, wherein the organic dopant forms a bound polaron and a free polaron in the photoelectric conversion layer, and
wherein the ratio of the density of the bound polarons to the density of the total polarons in the photoelectric conversion layer is about 10% to about 50%.

16. A method for manufacturing a photoelectric conversion layer for detecting SWIR, the method comprising:
preparing a film including a polymer represented by Formula 1 below;
coating a first doping solution on the film to perform a primary doping process on the polymer; and
coating a second doping solution on the film to perform a secondary doping process on the polymer,
wherein each of the first doping solution and the second doping solution includes an organic dopant represented by Formula 2 below, and
wherein a first solvent of the first doping solution and a second solvent of the second doping solution are different from each other: 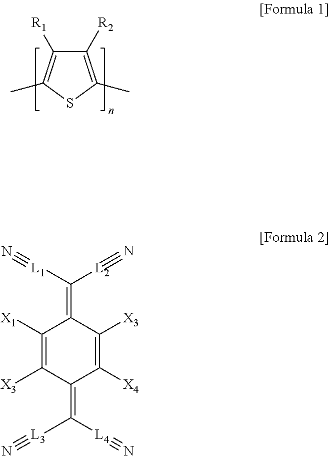
wherein in Formula 1 above, R₁ and R₂ are each independently hydrogen, or a substituted or unsubstituted C1-C20 alkyl group, and n is an integer between 10 to 10,000, and
wherein in Formula 2 above, X₁, X₂, X₃, and X₄ are each independently a halogen element selected from the group consisting of fluorine (F), chlorine (Cl), bromine (Br), and iodine (I), and L₁, L₂, L₃, and L₄ are each independently a direct linkage, or a substituted or unsubstituted C1-C10 alkylene group.

17. The method of claim 16, wherein the second solvent is capable of swelling the polymer.

18. The method of claim 16, wherein the organic dopant forms a bound polaron and a free polaron in the film, wherein the ratio of the density of the bound polarons to the density of the total polarons in the film is 10% to 50%.

19. The method of claim 18, wherein, when SWIR light is incident on the film, the bound polaron is converted into the free polaron in response to the SWIR light.

20. The method of claim 16, wherein the coating of the first doping solvent and the coating of the second doping solution each comprises a spin-coating process.
